(19) United States
(12) Patent Application Publication
(10) Pub. No.: US 2022/0263491 A1
(43) Pub. Date: Aug. 18, 2022

(54) ACOUSTIC WAVE DEVICE AND COMMUNICATION APPARATUS

(71) Applicant: KYOCERA Corporation, Kyoto-shi, Kyoto (JP)

(72) Inventor: Motoki ITO, Ikoma-shi (JP)

(73) Assignee: KYOCERA Corporation, Kyoto-shi, Kyoto (JP)

(21) Appl. No.: 17/630,649

(22) PCT Filed: Jul. 14, 2020
(86) PCT No.: PCT/JP2020/027334

§ 371 Date: Jan. 27, 2022

(30) Foreign Application Priority Data
Jul. 30, 2019 (JP) 2019-140012

(51) Int. Cl. H03H 9/13; H03H 9/15; H03H 9/56

(52) U.S. Cl. CPC H03H 9/13; H03H 9/568; H03H 9/15

(57) ABSTRACT

An acoustic wave device includes a substrate, a multilayer film disposed on the substrate, a piezoelectric film disposed on the multilayer film, and a first excitation electrode and a second excitation electrode disposed on the piezoelectric film. The first excitation electrode has a plurality of first electrode fingers arranged with a first pitch p1 in a propagation direction of an acoustic wave. The second excitation electrode has a plurality of second electrode fingers arranged with a second pitch p2 in the propagation direction. The piezoelectric film is formed of a single crystal of LiTaO₃ or a single crystal of LiNbO₃. When t0 represents a thickness of the piezoelectric film, 1.15×p1≤p2, t0≤0.48×p1, and t0≥0.27×p2 are satisfied.

### TECHNICAL FIELD

The present disclosure relates to an acoustic wave device using an acoustic wave, and also relates to a communication apparatus including the acoustic wave device.

### BACKGROUND ART

Acoustic wave devices have been known in which a voltage is applied to an excitation electrode on a piezoelectric body to generate an acoustic wave propagating in the piezoelectric body. The excitation electrode is, for example, an interdigital transducer (IDT) electrode that includes a pair of comb-shaped electrodes. The comb-shaped electrodes each have a plurality of electrode fingers (resembling comb teeth) and are arranged, with their fingers interlocked with each other. In the acoustic wave device, for example, an acoustic standing wave having a wavelength that is approximately twice the pitch of the electrode fingers is formed. Such an acoustic wave device may include, on one piezoelectric body, a plurality of excitation electrodes that differ in the pitch of electrode fingers. The excitation electrodes with different pitches are used to form, for example, a so-called ladder filter (see, e.g., Patent Literatures 1 and 2).

### CITATION LIST

### Patent Literature

PTL 1: Japanese Unexamined Patent Application Publication No. 2016-072808
PTL 2: International Publication No. 2015/080045

### SUMMARY OF INVENTION

An acoustic wave device according to an aspect of the present disclosure includes a substrate, a multilayer film disposed on the substrate, a piezoelectric film disposed on the multilayer film, and a first excitation electrode and a second excitation electrode disposed on the piezoelectric film. The first excitation electrode has a plurality of first electrode fingers arranged with a first pitch in a propagation direction of an acoustic wave. The second excitation electrode has a plurality of second electrode fingers arranged with a second pitch in the propagation direction. The piezoelectric film is formed of a single crystal of LiTaO₃ or a single crystal of LiNbO₃. When p1 represents the first pitch, p2 represents the second pitch, and t0 represents a thickness of the piezoelectric film,

1.15×p1≤p2,

t0≤0.48×p1, and

t0≥0.27×p2, are satisfied.

A communication apparatus according to another aspect of the present disclosure includes the acoustic wave device described above, an antenna electrically connected to the filter of the acoustic wave device, and an integrated circuit element electrically connected to the antenna, with the filter interposed therebetween.

### BRIEF DESCRIPTION OF DRAWINGS

FIG. 1 is a plan view illustrating a configuration of part of an acoustic wave device according to an embodiment.

FIG. 2 is a cross-sectional view taken along line II-II in FIG. 1.

FIG. 3 is a circuit diagram schematically illustrating a configuration of a duplexer which is an example of the acoustic wave device illustrated in FIG. 1.

FIG. 4 is a diagram for explaining an evaluation index for evaluating characteristics of the acoustic wave device illustrated in FIG. 1.

FIG. 5 is a contour chart showing the effect of the thickness of a piezoelectric film and the pitch of electrode fingers on characteristics in a first configuration example.

FIG. 6 is a diagram showing the effect of the thicknesses of a multilayer film on the maximum value of the impedance phase in the first configuration example.

FIG. 7 is a contour chart showing the effect of the thickness of the piezoelectric film and the pitch of electrode fingers on characteristics in a second configuration example.

FIG. 8 is a diagram showing the effect of the thicknesses of the multilayer film on the maximum value of the impedance phase in the second configuration example.

FIG. 9 is a contour chart showing the effect of the thickness of the piezoelectric film and the pitch of electrode fingers on characteristics in a third configuration example.

FIG. 10 is a diagram showing the effect of the thicknesses of the multilayer film on the maximum value of the impedance phase in the third configuration example.

FIG. 11 is a diagram showing an example of an actually measured bandpass characteristic of a ladder filter according to Example.

FIG. 12 is a circuit diagram schematically illustrating a configuration of a communication apparatus which is an application of the acoustic wave device illustrated in FIG. 1.

### DESCRIPTION OF EMBODIMENTS

The contents of International Publication No. 2019/009246 (PCT/JP2018/025071, hereinafter referred to as Prior Application 1) may be cited in the present application by reference (Incorporation by Reference). One of the inventors of Prior Application 1, which was filed by the present applicant, is the inventor of the present application.

Embodiments of the present disclosure will now be described with reference to the drawings. Note that the drawings to be used in the description are schematic ones. For example, dimensions in the drawings are not necessarily to scale.

In the acoustic wave device according to the present disclosure, any direction may be defined as an upper or lower direction. In the following description, an orthogonal coordinate system composed of a D1 axis, a D2 axis, and a D3 axis will be defined for convenience. The term, such as “upper surface” or “lower surface”, may be used on the assumption that the positive side of the D3 axis is the upper side. Unless otherwise stated, the term “plan view” or “perspective plan view” refers to a view seen in the D3 direction. The D1 axis is defined to be parallel to the propagation direction of an acoustic wave propagating along the upper surface of a piezoelectric film (described below), the D2 axis is defined to be parallel to the upper surface of the piezoelectric film and orthogonal to the D1 axis, and the D3 axis is defined to be orthogonal to the upper surface of the piezoelectric film.

### (Basic Elements of Acoustic Wave Device)

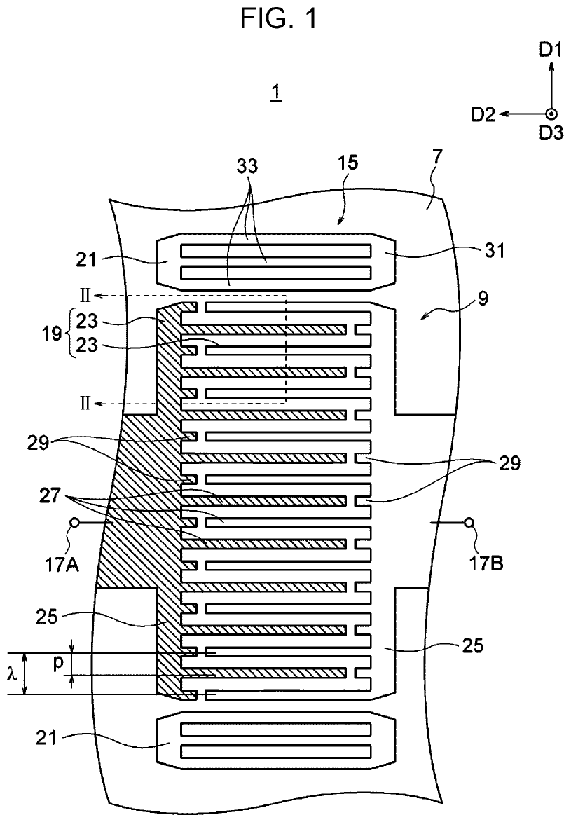

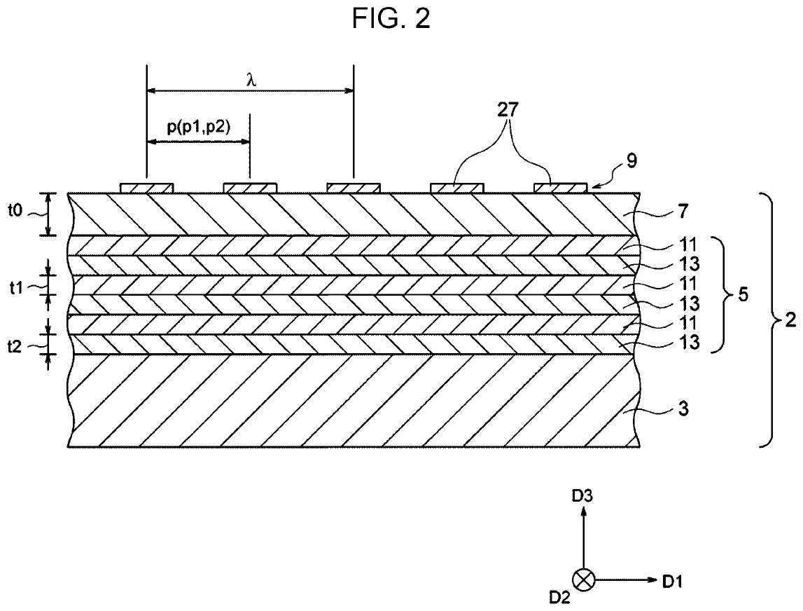

FIG. 1 is a plan view illustrating a configuration of part of an acoustic wave device 1. FIG. 2 is a cross-sectional view taken along line II-II in FIG. 1.

The acoustic wave device 1 includes, for example, a substrate 3 (FIG. 2), a multilayer film 5 (FIG. 2) disposed on the substrate 3, a piezoelectric film 7 disposed on the multilayer film 5, and a conductive layer 9 disposed on the piezoelectric film 7. Each layer has, for example, a substantially uniform thickness. The combination of the substrate 3, the multilayer film 5, and the piezoelectric film 7 may be referred to as a combined substrate 2 (FIG. 2).

In the acoustic wave device 1, applying a voltage to the conductive layer 9 excites an acoustic wave propagating in the piezoelectric film 7. The acoustic wave device 1 constitutes, for example, a resonator and/or filter that uses this acoustic wave. The multilayer film 5 contributes to, for example, confined energy of the acoustic wave in the piezoelectric film 7 by reflecting the acoustic wave. The substrate 3 contributes to, for example, reinforced strength of the multilayer film 5 and the piezoelectric film 7.

### (Combined Substrate)

The substrate 3 does not have a direct effect on the electrical characteristics of the acoustic wave device 1. Therefore, the material and dimensions of the substrate 3 may be appropriately set. For example, the substrate 3 is of an insulating material, such as resin or ceramic. The substrate 3 may be of a material having a lower thermal expansion coefficient than, for example, the piezoelectric film 7. This can reduce the probability that, for example, the frequency characteristics of the acoustic wave device 1 will be changed by changes in temperature. Examples of such a material include a semiconductor, such as silicon, a single crystal of sapphire, and a ceramic, such as sintered aluminum oxide. The substrate 3 may be a laminate of a plurality of layers of different materials. The substrate 3 has a greater thickness than, for example, the piezoelectric film 7.

The multilayer film 5 is a laminate of alternating first and second layers 11 and 13. The materials of the first and second layers 11 and 13 may be appropriately selected, for example, such that the acoustic impedance of the second layer 13 is higher than the acoustic impedance of the first layer 11. For example, this makes reflectivity of the acoustic wave relatively high at the interface between the first and second layers 11 and 13, and suppresses leakage of the acoustic wave propagating in the piezoelectric film 7. The material of the first layer 11 may be, for example, silicon dioxide (SiO₂). In this case, the material of the second layer 13 may be, for example, tantalum pentoxide (Ta₂O₅), hafnium oxide (HfO₂), zirconium dioxide (ZrO₂), titanium oxide (TiO₂), or magnesium oxide (MgO). In the description of the present embodiment, the second layer 13 of Ta₂O₅ or HfO₂ is specifically described as an example.

The number of layers of the multilayer film 5 may be appropriately set. For example, the total number of the first and second layers 11 and 13 of the multilayer film 5 may be greater than or equal to 3 and less than or equal to 12. The multilayer film 5 may be composed of a total of two layers, one first layer 11 and one second layer 13. Although the total number of layers of the multilayer film 5 may be either an even or odd number, the layer in contact with the piezoelectric film 7 is, for example, the first layer 11. The layer in contact with the substrate 3 may be either the first layer 11 or the second layer 13.

The thicknesses of the multilayer film may be appropriately set. For example, the pitch of electrode fingers 27 (described below) is denoted by the letter p. In this case, a thickness t1 of the first layer 11 may be greater than or equal to 0.10p or greater than or equal to 0.14p, and may be smaller than or equal to 0.28p or smaller than or equal to 0.26p. These lower and upper limits may be appropriately combined. Also, for example, a thickness t2 of the second layer 13 may be greater than or equal to 0.08p or greater than or equal to 1.90p, and may be smaller than or equal to 2.00p or smaller than or equal to 0.20p. These lower and upper limits may be appropriately combined, as long as there is no discrepancy.

The first and second layers 11 and 13 may be provided with an additional layer inserted therebetween for improved adhesion or reduced diffusion. The thickness of the additional layer is small enough to have only a negligible effect on the characteristics. For example, the thickness of the additional layer is about 0.01λ or less (λ will be described later on below). Even when such an additional layer is provided, the presence of the additional layer may not be specifically mentioned in the description of the present disclosure. The same applies to the case of adding such a layer, for example, between the piezoelectric film 7 and the multilayer film 5.

The piezoelectric film 7 is formed of a single crystal of lithium tantalate (LiTaO₃, which may hereinafter be abbreviated as “LT”) or a single crystal of lithium niobate (LiNbO₃, which may hereinafter be abbreviated as “LN”). LT and LN both have a trigonal crystal system that belongs to a piezoelectric point group 3m. The cut angles of the piezoelectric film 7 may be of various types including known cut angles. For example, the piezoelectric film 7 may be of a rotated Y-cut X-propagation type. That is, the acoustic wave propagation direction (D1 direction) may substantially coincide with the X axis (e.g., the difference between them is ±10°). In this case, the angle of inclination of the Y axis with respect to a line normal to the piezoelectric film (D3 axis) may be appropriately set.

Specifically, for example, when the material of the piezoelectric film 7 is LT, the piezoelectric film 7 may be one that is expressed in Euler angles (ϕ, θ, ψ) as (0°±20°, −5° or more and 65° or less, 0°±10°). In another respect, the piezoelectric film 7 may be of a rotated Y-cut X-propagation type, and the Y axis may be inclined at an angle of 85° or more and 155° or less with respect to a line normal to the piezoelectric film 7 (D3 axis). The piezoelectric film 7 expressed in Euler angles equivalent to those described above may be used. Examples of the Euler angles equivalent to those described above include (180°±10°, −65° to 5°, 0°±10°) and those obtained by adding or subtracting 120° to or from ϕ.

When the material of the piezoelectric film 7 is LN, the piezoelectric film 7 may be one that is expressed in Euler angles (ϕ, θ, ψ) as (0°, 0°±20°, X°), where X° is a value greater than or equal to 0° and smaller than or equal to 360°. That is, X° may be an angle of any value.

### (Conductive Layer)

The conductive layer 9 is made of, for example, metal. The metal may be of any appropriate type and may be, for example, aluminum (Al) or an alloy composed primarily of Al (Al alloy). The Al alloy is, for example, an aluminum-copper (Cu) alloy. The conductive layer 9 may be composed of a plurality of metal layers. For example, the Al or Al alloy layer and the piezoelectric film 7 may be provided with a relatively thin layer of titanium (Ti) therebetween for enhanced bonding. The thickness of the conductive layer 9 may be appropriately set. For example, the thickness of the conductive layer 9 may be greater than or equal to 0.04p and smaller than or equal to 0.17p.

In the example illustrated in FIG. 1, the conductive layer 9 is formed to constitute the resonator 15. The resonator 15 is configured as a so-called one-port acoustic wave resonator. The resonator 15 resonates when an input electric signal with a predetermined frequency is received from one of terminals 17A and 17B that are conceptually and schematically illustrated. The resonator 15 can then output the resonating signal from the other of the terminals 17A and 17B.

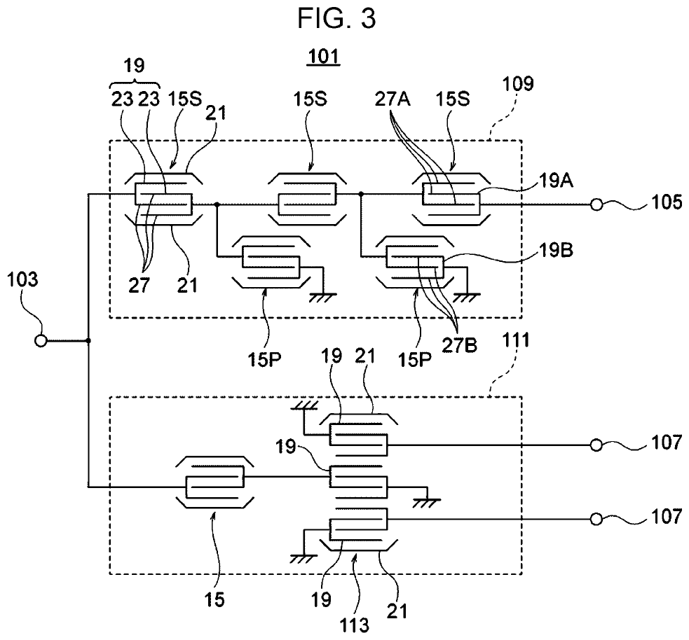

The conductive layer 9 (resonator 15) includes, for example, an excitation electrode 19 and a pair of reflectors 21 disposed on both sides of the excitation electrode 19. The resonator 15 includes the piezoelectric film 7 and the multilayer film 5 in a strict sense. As described below, however, a plurality of combinations of the excitation electrode 19 and the pair of reflectors 21 may be provided on one piezoelectric film 7 to form a plurality of resonators 15 (see FIG. 3). In the following description, therefore, a combination of the excitation electrode 19 and one reflector 21 (electrode portion of the resonator 15) may be referred to as the resonator 15 for convenience.

The excitation electrode 19 is constituted by an IDT electrode and includes a pair of comb-shaped electrodes 23. One of the comb-shaped electrodes 23 is hatched for ease of viewing. Each of the comb-shaped electrodes 23 includes, for example, a busbar 25, a plurality of electrode fingers 27 extending in parallel from the busbar 25, and dummy electrodes 29 protruding between adjacent ones of the plurality of electrode fingers 27 from the busbar 25. The pair of comb-shaped electrodes 23 is disposed, with the plurality of electrode fingers 27 interlocked with (or overlapping) each other.

The busbar 25 is, for example, an elongated member having a substantially uniform width and linearly extending in the acoustic wave propagation direction (D1 direction). The busbars 25 constituting a pair are opposite each other in a direction (D2 direction) orthogonal to the acoustic wave propagation direction. The busbars 25 may vary in width or may be inclined with respect to the acoustic wave propagation direction.

The electrode fingers 27 are each, for example, an elongated member having a substantially uniform width and linearly extending in the direction (D2 direction) orthogonal to the acoustic wave propagation direction. In each of the comb-shaped electrodes 23, the plurality of electrode fingers 27 are arranged in the acoustic wave propagation direction. The plurality of electrode fingers 27 of one of the comb-shaped electrodes 23 and the plurality of electrode fingers 27 of the other of the comb-shaped electrodes 23 are basically alternately arranged.

A pitch p (e.g., center-to-center distance between two electrode fingers 27 adjacent to each other) of the plurality of electrode fingers 27 is basically uniform in the excitation electrode 19. The excitation electrode 19 may have a distinct portion that varies in terms of the pitch p. Examples of the distinct portion include a narrow pitch portion where the pitch p is narrower than in most other part (e.g., 80% or above), a wide pitch portion where the pitch p is wider than in most other part, and a reduced portion where a few of the electrode fingers 27 are practically removed.

Unless otherwise stated, the term “pitch p” described herein refers to a pitch in most part (i.e., the pitch of most of the plurality of electrode fingers 27) except a distinct portion, such as that described above. If the pitch of the plurality of electrode fingers 27 in most part, except the distinct portion, varies, the average of the pitches of most of the plurality of electrode fingers 27 may be used as the value of the pitch p.

The number of the electrode fingers 27 may be appropriately set, for example, in accordance with the electrical characteristics required for the resonator 15. The electrode fingers 27 illustrated in FIG. 1, which is a schematic diagram, are fewer than actual ones. More electrode fingers 27 than those illustrated may be arranged in practice. The same applies to strip electrodes 33 (described below) of each reflector 21.

The plurality of electrode fingers 27 have, for example, an equal length. To vary the length (or overlapping width, in another respect) of the plurality of electrode fingers 27 depending on the position in the propagation direction, so-called apodization may be applied to the excitation electrode 19. The length and width of the electrode fingers 27 may be appropriately set, for example, in accordance with the electrical characteristics required.

The dummy electrodes 29 have, for example, a substantially uniform width and protrude in a direction orthogonal to the acoustic wave propagation direction. The width of the dummy electrodes 29 is substantially the same as that of, for example, the electrode fingers 27. The dummy electrodes 29 and the electrode fingers 27 are arranged with the same pitch. An end portion of each dummy electrode 29 of one of the comb-shaped electrodes 23 and an end portion of the corresponding one of the electrode fingers 27 of the other of the comb-shaped electrodes 23 face each other, with a gap therebetween. The excitation electrode 19 may be one that does not include the dummy electrodes 29.

The reflectors 21 constituting a pair are disposed on both sides of a plurality of excitation electrodes 19 in the acoustic wave propagation direction. For example, each of the reflectors 21 may be in an electrically floating state or may be applied with a reference potential. The reflectors 21 are each formed, for example, in a grid pattern. That is, the reflectors 21 each include a pair of busbars 31 opposite each other, and the plurality of strip electrodes 33 extending between the busbars 31. The pitch of the plurality of strip electrodes 33 and the pitch of the electrode finger 27 and the strip electrode 33 adjacent each other are basically the same as the pitch of the plurality of electrode fingers 27.

While not specifically shown, the upper surface of the piezoelectric film 7 may be covered with a protective film of, for example, SiO₂ or Si₃N₄ lying over the conductive layer 9. The protective film may be a laminate of a plurality of layers of these materials. The protective film may be designed to simply prevent corrosion of the conductive layer 9, or may be designed to contribute to temperature compensation. For example, when the protective film is provided, an insulating or metal film may be added to the upper or lower surface of the excitation electrode 19 and reflectors 21 to improve the reflection coefficient of the acoustic wave.

The structure illustrated in FIG. 1 and FIG. 2 may be appropriately packaged. For example, the packaging may involve mounting the illustrated structure onto a substrate (not shown), with the upper surface of the piezoelectric film 7 facing the substrate, while leaving a gap therebetween, and then sealing the resulting product with resin from above. Alternatively, a wafer-level packaging technique may be used which involves covering the piezoelectric film 7 with a box-shaped cover from above.

When a voltage is applied to the pair of comb-shaped electrodes 23, the plurality of electrode fingers 27 apply the voltage to the piezoelectric film 7. This causes the piezoelectric film 7, which is a piezoelectric body, to vibrate and excites an acoustic wave that propagates in the D1 direction. The acoustic wave is reflected by the plurality of electrode fingers 27. This generates a standing wave whose half-wavelength (λ/2) is substantially equal to the pitch p of the plurality of electrode fingers 27. An electric signal generated in the piezoelectric film 7 by the standing wave is extracted by the plurality of electrode fingers 27. On the basis of this principle, the acoustic wave device 1 functions as a resonator having a resonance frequency which is equal to the frequency of an acoustic wave whose half-wavelength is equal to the pitch p. Generally, λ is a letter representing a wavelength. Although the wavelength of an acoustic wave may deviate from 2p in practice, λ means 2p in the following description unless otherwise stated.

An acoustic wave of any appropriate mode may be used. For example, in the configuration where the piezoelectric film 7 is disposed over the multilayer film 5 as in the present embodiment, a slab mode acoustic wave may be used. The propagation speed (acoustic velocity) of a slab mode acoustic wave is faster than the propagation speed of a typical surface acoustic wave (SAW). For example, the propagation speed of a typical SAW ranges from 3000 m/s to 4000 m/s, whereas the propagation speed of a slab mode acoustic wave is 10000 m/s or faster. Accordingly, using a slab mode acoustic wave makes it easier to achieve resonance and/or filtering in a relatively high frequency region. For example, a resonance frequency of 5 GHz or more can be achieved with a pitch p of 1 μm or more.

### (Example of Acoustic Wave Device: Duplexer)

The acoustic wave device 1 includes a plurality of excitation electrodes 19 with different pitches p. A multiplexer (or more specifically, a duplexer) will now be described as an example of the acoustic wave device 1.

FIG. 3 is a circuit diagram schematically illustrating a configuration of a duplexer 101 which is an example of the acoustic wave device 1. As can be seen by the symbols appearing in the upper left of the drawing, the comb-shaped electrodes 23 are each schematically illustrated in the form of a two-pronged fork, and the reflectors 21 are each represented by a single line that bends at both ends.

The duplexer 101 includes, for example, a transmission filter 109 configured to filter a transmission signal from a transmission terminal 105 and output the resulting signal to an antenna terminal 103, and a reception filter 111 configured to filter a reception signal from the antenna terminal 103 and output the resulting signal to a pair of reception terminals 107. Although the entire duplexer 101 is taken as an example of the acoustic wave device 1 here, the transmission filter 109 and the reception filter 111 may each be taken as an example of the acoustic wave device 1.

The transmission filter 109 is constituted, for example, by a ladder filter that includes a plurality of resonators 15 connected in a ladder configuration. That is, the transmission filter 109 includes a plurality of (or one) series resonators 15S connected in series between the transmission terminal 105 and the antenna terminal 103, and a plurality of (or one) parallel resonators 15P (parallel arms) configured to connect the series line (series arm) to the reference potential. The series resonators 15S and the parallel resonators 15P have the same configuration as the resonator 15 illustrated in FIG. 1. Hereinafter, the series resonators 15S and the parallel resonators 15P may each be simply referred to as a resonator 15. The plurality of resonators 15 constituting the transmission filter 109 are provided, for example, on the same combined substrate 2 (3, 5, and 7).

The reception filter 111 includes, for example, the resonator 15 and a multimode filter (including a double mode filter) 113. The multimode filter 113 includes a plurality of (three in the illustrated example) excitation electrodes 19 arranged in the acoustic wave propagation direction, and a pair of reflectors 21 arranged on both sides of the excitation electrodes 19. The resonator 15 and the multimode filter 113 constituting the reception filter 111 are provided, for example, on the same combined substrate 2.

The transmission filter 109 and the reception filter 111 may be provided, for example, either on the same combined substrate 2 or on different combined substrates 2. FIG. 3 illustrates merely an exemplary configuration of the duplexer. For example, like the transmission filter 109, the reception filter 111 may be constituted by a ladder filter.

In the ladder filter (transmission filter 109), the pitch p in the series resonator 15S and the pitch p in the parallel resonators 15P differ from each other. Specifically, these pitches p are set such that the resonance frequency (described below) of the series resonators 15S substantially matches the antiresonance frequency (described below) of the parallel resonators 15P. The matching frequency is a center frequency at substantially the center of the pass band of the ladder filter. As described above, the duplexer 101 or the transmission filter 109 serving as the acoustic wave device 1 includes the excitation electrodes 19 having different pitches p on the same piezoelectric film 7.

Since the transmission filter 109 and the reception filter 111 have different pass bands, the pitches p in these filters are different. Accordingly, when both filters are on the same piezoelectric film 7, the duplexer 101, which is the acoustic wave device 1, includes the excitation electrodes 19 with different pitches p on the same piezoelectric film 7 because of the difference in the pass band between the filters.

### (Two Types of Excitation Electrodes)

As described above, the acoustic wave device 1 includes a plurality of excitation electrodes 19 with different pitches p on the same piezoelectric film 7. In the following description, the excitation electrode 19 having a pitch p1 as the pitch p may be referred to as a first excitation electrode 19A, and the excitation electrode 19 having a pitch p2 greater than the pitch p1 as the pitch p may be referred to as a second excitation electrode 19B. As denoted in FIG. 3, the excitation electrode 19 of the series resonator 15S is an example of the first excitation electrode 19A, and the excitation electrode 19 of the parallel resonator 15P is an example of the second excitation electrode 19B.

Generally, the difference in pitch between the excitation electrodes 19 on the same piezoelectric body is relatively small. However, the present embodiment proposes the acoustic wave device 1 in which the difference between the pitch p1 and the pitch p2 is relatively large. For example, the difference between the pitch p1 and the pitch p2 is 15% or more of the pitch p1. That is, the acoustic wave device 1 may satisfy the following relation:

1.15×p1≤p2 (1).

With the pitches p1 and p2 having a large difference, for example, the characteristics of a ladder filter having the piezoelectric film 7 on the multilayer film 5 can be improved. Specifically, in the ladder filter, for example, when the pitch p in the parallel resonator 15P is set greater than the pitch p in the series resonator 15S, a resonance frequency of the parallel resonator 15P and an antiresonance frequency of the parallel resonator 15P higher than the resonance frequency are shifted toward lower frequencies. The antiresonance frequency of the parallel resonator 15P thus matches the resonance frequency of the series resonator 15S. Generally, the difference in pitch between the series resonator 15S and the parallel resonator 15P is relatively small. In the configuration where the piezoelectric film 7 is on the multilayer film 5, however, even when the pitch p in the parallel resonator 15P is made as large as that in a typical acoustic wave device, the resonance frequency and the antiresonance frequency of the parallel resonator 15P may not be shifted toward lower frequencies by a desired amount. That is, the amount of shift of the resonance frequency and the antiresonance frequency toward lower frequencies may be small, relative to the amount of increase in pitch p. Moreover, the antiresonance frequency of the parallel resonator 15P may not even match the resonance frequency of the series resonator 15S. Accordingly, the pitches p1 and p2 are set such that the pitch p2 in the parallel resonator 15P is greater than the pitch p1 in the series resonator 15S by 15% or more. This allows the resonance frequency of the series resonator 15S and the antiresonance frequency of the parallel resonator 15P to match and improves the characteristics of the ladder filter.

When the difference between the pitches p1 and p2 increases, the characteristics of at least one of the first excitation electrode 19A and the second excitation electrode 19B may be degraded. Accordingly, the present disclosure also proposes conditions (e.g., thickness t0 of the piezoelectric film 7) that have a high probability of maintaining good characteristics of both the first excitation electrode 19A and the second excitation electrode 19B. As described above, the difference in pitch between the excitation electrodes 19 is generally small and it is less likely that the characteristics of one of the excitation electrodes 19 will be degraded. Therefore, although there is literature, such as Prior Application 1, that discusses the preferred range of the thickness of, for example, the piezoelectric film 7 normalized at the pitch p (or λ which is twice the pitch p), there will be no literature that discusses the relation between three factors, that is, the thickness of a predetermined component, two pitches p (or possible range of the pitch p in another respect), and characteristics.

### (Evaluation Index)

The following discussion evaluates the characteristics of the acoustic wave device 1 on the basis of a predetermined evaluation index and identifies the conditions (e.g., the thickness t0 of the piezoelectric film 7) that can improve the characteristics. A maximum value θmax of an impedance phase θz is used as an example of the evaluation index. The description of θmax is given below.

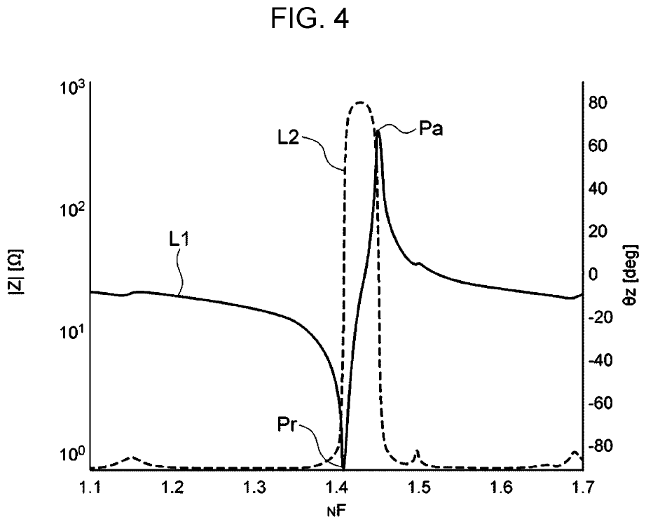

FIG. 4 is a diagram for explaining an evaluation index for evaluating characteristics of the excitation electrode 19.

This diagram shows an example of impedance characteristics of one resonator 15. In the diagram, the horizontal axis represents normalized frequency NF (no units), the vertical axis on the left side represents absolute impedance |Z| (Ω), and the vertical axis on the right side represents impedance phase θz (°), where NF=f×2p/c, f is frequency, and c is acoustic velocity. A line L1 represents a change of the absolute impedance |Z| with respect to the normalized frequency, and a line L2 represents a change of the impedance phase θz with respect to the normalized frequency.

The resonator 15 has a resonance point Pr at which the absolute impedance |Z| reaches a relative minimum, and an antiresonance point Pa at which the absolute impedance reaches a relative maximum. The frequency at the resonance point Pr is a resonance frequency, and the frequency at the antiresonance point Pa is an antiresonance frequency. The impedance phase θz approaches 90° substantially in the frequency range between the antiresonance frequency and the resonance frequency, and approaches −90° outside the frequency range. The closer the phase θz is to 90° in the frequency range between the antiresonance frequency and the resonance frequency, the smaller the insertion loss of the resonator 15. The maximum value θmax of the impedance phase θz is the largest value of the phase θz that changes with respect to frequency. Generally, the greater the maximum value θmax, the smaller the insertion loss.

In the following discussion, where the conditions of the reflectors 21 are the same, changes in characteristics associated with changes in various conditions may be regarded as changes in the characteristics of the excitation electrode 19. That is, the findings described below are applicable not only to the resonator 15, but also to various elements (e.g., multimode filter) including the excitation electrode 19.

### (Piezoelectric Film and Multilayer Film to be Simulated)

A simulation was performed for each of the following three configuration examples that vary in the materials of the piezoelectric film 7 and the multilayer film 5.

First Configuration Example:
piezoelectric film 7: LT
first layer 11: SiO₂
second layer 13: Ta₂O₅

Second Configuration Example:
piezoelectric film 7: LT
first layer 11: SiO₂
second layer 13: HfO₂

Third Configuration Example:
piezoelectric film 7: LN
first layer 11: SiO₂
second layer 13: Ta₂O₅

Simulation conditions common to all the configuration examples are shown below. A silicon substrate was used as the support substrate 3.

Conductive Layer:
material: Al
thickness: 0.1 to 0.15p

Number of first layers: 4

Number of second layers: 4

### First Configuration Example

### (Thickness of Piezoelectric Film)

The pitch p of the electrode fingers 27 and the thickness t0 of the piezoelectric film 7 were variously set to determine the characteristics of the resonator 15 by simulated calculations. Simulation conditions other than the pitch p and the thickness t0 are as follows.

Piezoelectric Film:
material: LT
Euler angles: (0°, 16°, 0°)

First Layer:
material: SiO₂
thickness: set in accordance with the value of t0 to satisfy t0:t1=0.35:0.18

Second Layer:
material: Ta₂O₅

thickness: set in accordance with the value of t0 to satisfy t0:t2=0.35:0.14

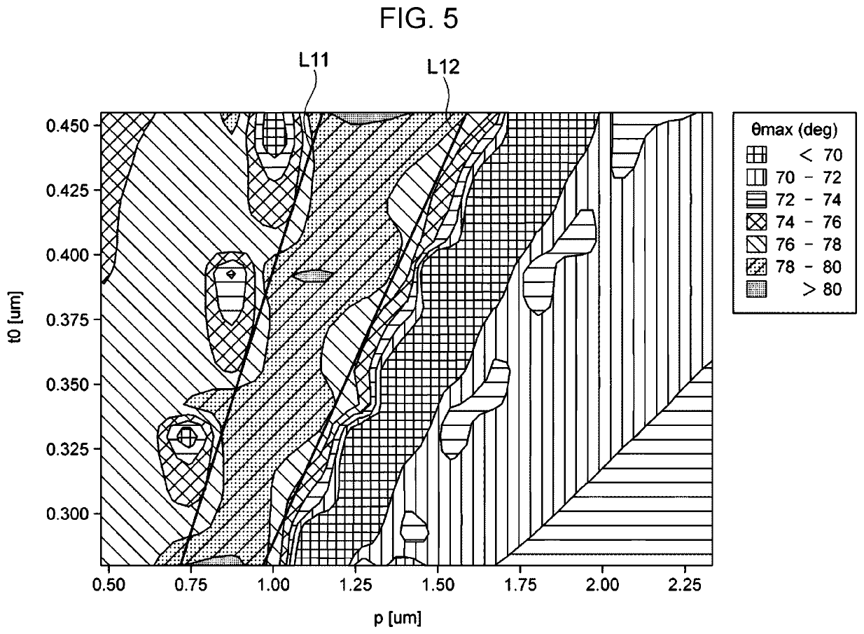

FIG. 5 is a contour chart showing a result of calculation of the maximum value θmax of the impedance phase in the first configuration example. In this chart, the horizontal axis represents the pitch p (μm) of the electrode fingers 27, and the vertical axis represents the thickness t0 (μm) of the piezoelectric film 7. Contour lines each represent the maximum value θmax (°). A line L11 and a line L12 are straight lines indicating a range where the maximum value θmax is about 78° or more (or at least 76° in another respect).

As illustrated in this chart, the plurality of contour lines extend substantially from the lower left to the right side of the drawing. This confirmed that the thickness t0 of the piezoelectric film 7 with which a desired maximum value θmax is achieved could be defined by its ratio to the pitch p.

When attention is focused on one value of the thickness t0, the value of the pitch p at which the maximum value θmax is a predetermined value or more (e.g., about 78° or more, or at least) 76° is found to have a certain range. For example, the space between the line L11 and the line L12 (distance parallel to the horizontal axis) is 0.25 μm or more. Also, in the illustrated example, a region where the pitch p is about 1 μm is sandwiched between the line L11 and the line L12. It was thus confirmed that since 0.25 μm is 15% or more of 1 μm, the difference between the pitches p1 and p2 in the first excitation electrode 19A and the second excitation electrode 19B on the same piezoelectric film 7 could be set to 15% or more of the pitch p1.

As described above, the range of the thickness t0 where a desired maximum value θmax is obtained can be normalized by dividing the value of the range by the value of the pitch p. In the case of p=1 μm, t0 (μm)/p (μm)=t0 (no units) is satisfied. For example, in the case of t0=0.35 μm, t0 (μm)/1 (μm)=0.35 (no units) is satisfied. Therefore, in FIG. 5, the range of the value of the thickness t0 (μm) in the region from the line L12 to the line L11 when the pitch p is 1 μm can be regarded as the range of a normalized value of t0 (no units).

A line (not shown) parallel to the vertical axis at p=1 μm intersects the lines L12 and L11 at thicknesses t0 of 0.29 μm and 0.40 μm, respectively. Accordingly, when the pitches p1 and p2 satisfy the following relation (2) and relation (3), both the first excitation electrode 19A and the second excitation electrode 19B can provide a desired maximum value θmax (about 78° or more, or at least 76°):

0.29×p1≤t0≤0.40×p1 (2),

0.29×p2≤t0≤0.40×p2 (3).

Because of p1<p2, the inequality on the right side of relation (3) is satisfied when the inequality on the right side of relation (2) is satisfied. Similarly, the inequality on the left side of relation (2) is satisfied when the inequality on the left side of relation (3) is satisfied. Accordingly, relation (2) and relation (3) can be replaced by the following relations:

t0≤0.40×p1 (4),

t0≥0.29×p2 (5).

Note that in the inequalities representing the range of thickness, values are each rounded off to decimal places of the numbers specified above. For example, 0.15 in relation (1) includes 0.146 and 0.154, 0.40 in relation (4) includes 0.396 and 0.404, and 0.29 in relation (5) includes 0.286 and 0.294. The same applies to various other relations described below.

In connection with relation (4) and relation (5), the upper limit of the pitch p2 relative to the pitch p1 is defined. That is, to satisfy both of the relations, the following relation needs to be satisfied:

0.29×p2≤0.40×p1 (6).

Dividing both sides of (6) by 0.29 yields the following relation:

p2≤1.4×p1 (7).

Dividing the value of the pitch p on the line L12 corresponding to one value of the thickness t0 by the value of the pitch p on the line L11 corresponding to the one value in FIG. 5 yields approximately 1.4, which substantially matches the coefficient in relation (7). This also indicates that relation (4) and relation (5) are valid.

### (Thicknesses of Multilayer Film)

In the simulation described above, the thickness t1 of the first layer 11 and the thickness t2 of the second layer 13 were each set to have a predetermined ratio with respect to the thickness t0 of the piezoelectric film 7. These ratios were selected in such a way as to make the maximum value θmax of the impedance phase greater. The details will now be described.

With the value of the thickness t0 kept constant, the values of the thickness t1 and the thickness t2 were variously set to perform simulated calculations and determine the characteristics of the resonator 15 by the simulated calculations. The simulation conditions used here are substantially the same as the simulation conditions for FIG. 5. Simulation conditions different from those for FIG. 5 are shown below:

thickness t0 of piezoelectric film: 0.35 μm,

thickness t1 of first layer: 0.14 μm to 0.22 μm,

thickness t2 of second layer: 0.09 μm to 0.18 μm.

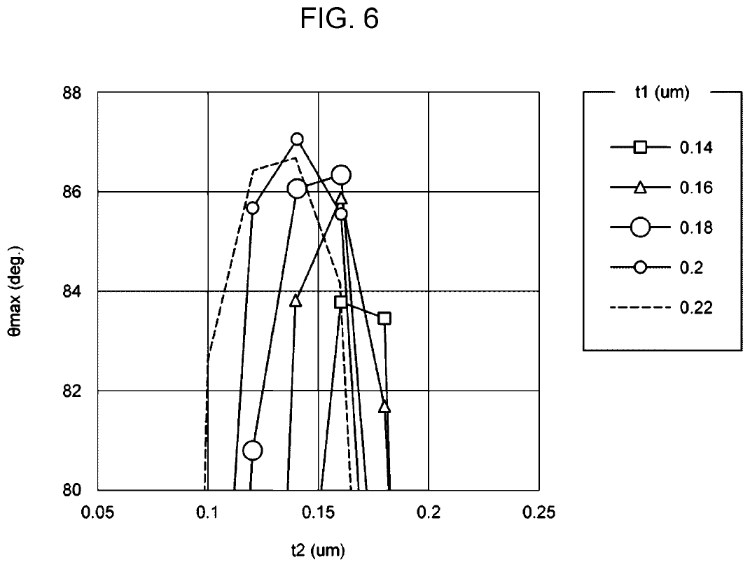

FIG. 6 is a diagram showing the maximum value θmax of the impedance phase calculated in the simulation described above. In this diagram, the horizontal axis represents the thickness t2, and the vertical axis represents the maximum value θmax. As indicated on the right side of the drawing, lines in the diagram each represent a relation between the thickness t2 and the maximum value θmax for one of thicknesses t1 having different values.

As shown in the diagram, the maximum value θmax is large when t1=0.18 μm and t2=0.14 μm. The ratio between the thicknesses t0, t1, and t2 at this point is as follows, as also mentioned in the description of the simulation conditions for FIG. 5:

t0:t1:t2=0.35:0.18:0.14.

FIG. 6 shows that even when the value of the thickness t1 and/or the thickness t2 differs by about 0.02 μm from a value corresponding to the ratio, a large maximum value θmax can be obtained. Since 0.02 μm is greater than 5% of the thickness t0 (0.35 μm), the thickness t1 and the thickness t2 may each be set to fall within ±5% of the ratio described above. That is, the thickness t1 and the thickness t2 may each be in the range defined by a corresponding one of the following relations:

0.49×t0≤t1≤0.54×t0 (8),

0.38×t0≤t2≤0.42×t0 (9).

The coefficients in relation (8) and relation (9) are determined by the following equations:

0.49=0.18/0.35×0.95,

0.54=0.18/0.35×1.05,

0.38=0.14/0.35×0.95,

0.42=0.14/0.35×1.05.

Note that the sign “=” is used even in the case of “≈”. The same applies to the corresponding equations in the other configuration examples described below.

### Second Configuration Example

### (Thickness of Piezoelectric Film)

As in the first configuration example described above, the pitch p of the electrode fingers 27 and the thickness t0 of the piezoelectric film 7 were variously set to determine the characteristics of the resonator 15 by simulated calculations. Simulation conditions other than the pitch p and the thickness t0 are as follows.

Piezoelectric Film:
material: LT
Euler angles: (0°, 16°, 0°)

First Layer:
material: SiO₂
thickness: set in accordance with the value of t0 to satisfy t0:t1=0.40:0.20

Second Layer:
material: HfO₂
thickness: set in accordance with the value of t0 to satisfy t0:t2=0.40:0.16

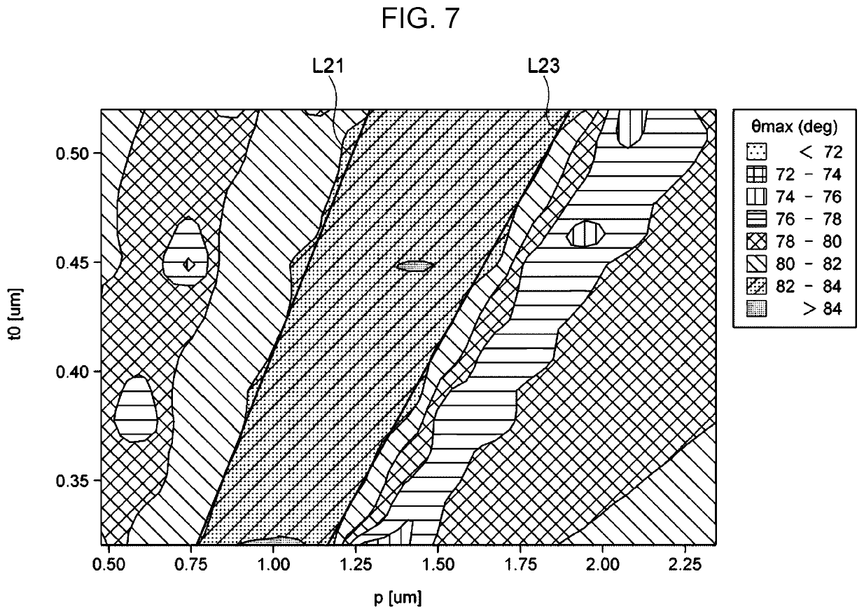

FIG. 7 is a contour chart showing a result of calculation of the maximum value θmax of the impedance phase in the second configuration example. FIG. 7 corresponds to FIG. 5. In this chart, a line L21 and a line L22 are straight lines indicating a range where the maximum value θmax is about 82° or more.

In FIG. 7, as in FIG. 5, the plurality of contour lines extend substantially from the lower left to the right side of the drawing. This confirmed that the thickness t0 of the piezoelectric film 7 with which a desired maximum value θmax is achieved could be defined by its ratio to the pitch p.

In FIG. 7, when attention is focused on one value of the thickness t0 as in FIG. 5, the value of the pitch p at which the maximum value θmax is a predetermined value or more (e.g., 82° or more) is found to have a certain range. For example, the space between the line L21 and the line L22 (distance parallel to the horizontal axis) is 0.4 μm or more. Also, in the illustrated example, a region where the pitch p is about 1 μm is sandwiched between the line L21 and the line L22. It was thus confirmed that since 0.4 μm is 15% or more of 1 μm, the difference between the pitches p1 and p2 in the first excitation electrode 19A and the second excitation electrode 19B on the same piezoelectric film 7 could be set to 15% or more of the pitch p1.

In FIG. 7, as in FIG. 5, a line (not shown) parallel to the vertical axis at p=1 μm intersects the lines L22 and L21 at thicknesses t0 of 0.27 μm and 0.41 μm, respectively. Note that 0.27 μm was determined by extrapolating the line L22 to the outside of the range of FIG. 5. From the values described above, the following relation (10) and relation (11) can be obtained, as in the first configuration example. When these relations are satisfied, both the first excitation electrode 19A and the second excitation electrode 19B can provide a desired maximum value θmax (82° or more):

t0≤0.41×p1 (10),

t0≥0.27×p2 (11).

In connection with relation (10) and relation (11), the upper limit of the pitch p2 relative to the pitch p1 is defined, as in the first configuration example. That is, to satisfy both of the relations, the following relation using 0.41/0.27 (=about 1.5) needs to be satisfied:

p2≤1.5×p1 (12).

Dividing the value of the pitch p on the line L22 corresponding to one value of the thickness t0 by the value of the pitch p on the line L21 corresponding to the one value in FIG. 7 yields approximately 1.5, which substantially matches the coefficient in relation (12). This also indicates that relation (10) and relation (11) are valid.

### (Thicknesses of Multilayer Film)

In the second configuration example, as in the first configuration example, the ratios of the thickness t1 of the first layer 11 and the thickness t2 of the second layer 13 to the thickness t0 of the piezoelectric film 7 in the simulation described above were selected in such a way as to make the maximum value θmax of the impedance phase greater. The details will now be described.

With the value of the thickness t0 kept constant, the values of the thickness t1 and the thickness t2 were variously set to perform simulated calculations and determine the characteristics of the resonator 15 by the simulated calculations. The simulation conditions used here are substantially the same as the simulation conditions for FIG. 7. Simulation conditions different from those for FIG. 7 are shown below:

thickness t0 of piezoelectric film: 0.40 μm,

thickness t1 of first layer: 0.16 μm to 0.24 μm,

thickness t2 of second layer: 0.06 μm to 0.28 μm.

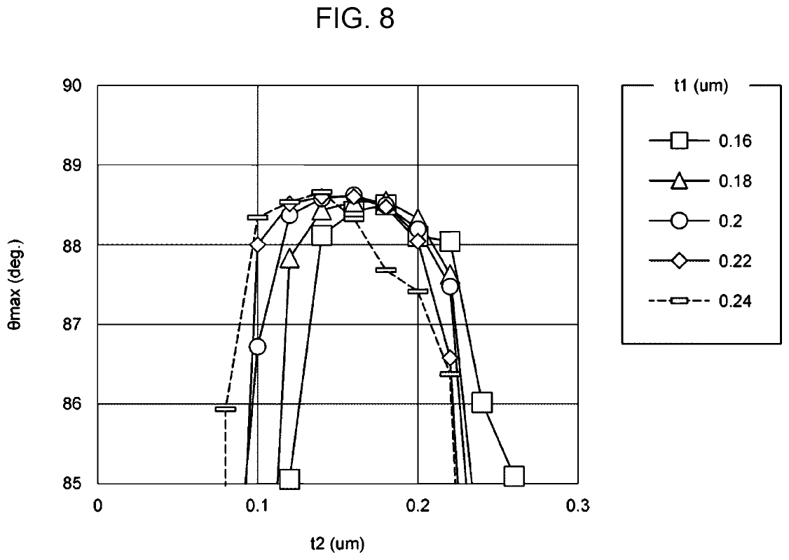

FIG. 8 is a diagram showing the maximum value θmax of the impedance phase calculated in the simulation described above. FIG. 8 corresponds to FIG. 6.

As shown in the diagram, the maximum value θmax is large when t1=0.20 μm and t2=0.16 μm. The ratio between the thicknesses t0, t1, and t2 at this point is as follows, as also mentioned in the description of the simulation conditions for FIG. 7:

t0:t1:t2=0.40:0.20:0.16.

FIG. 8 shows that even when the value of the thickness t1 and/or the thickness t2 differs by about 0.02 μm from a value corresponding to the ratio, a large maximum value θmax can be obtained. Since 0.02 μm is 5% of the thickness t0 (0.40 μm), the thickness t1 and the thickness t2 may each be set to fall within ±5% of the ratio described above, as in the first configuration example. That is, the thickness t1 and the thickness t2 may each be in the range defined by a corresponding one of the following relations:

0.48×t0≤t1≤0.53×t0 (13),

0.38×t0≤t2≤0.42×t0 (14).

The coefficients in relation (13) and relation (14) are determined by the following equations:

0.48=0.20/0.40×0.95,

0.53=0.20/0.40×1.05,

0.38=0.16/0.40×0.95,

0.42=0.16/0.40×1.05.

### Third Configuration Example

### (Thickness of Piezoelectric Film)

As in the first configuration example described above, the pitch p of the electrode fingers 27 and the thickness t0 of the piezoelectric film 7 were variously set to determine the characteristics of the resonator 15 by simulated calculations. Simulation conditions other than the pitch p and the thickness t0 are as follows.

Piezoelectric Film:
material: LN
Euler angles: (0°, 0°, 0°)

First Layer:
material: SiO₂
thickness: set in accordance with the value of t0 to satisfy t0:t1=0.38:0.20

Second Layer:
material: Ta₂O₅
thickness: set in accordance with the value of t0 to satisfy t0:t2=0.38:0.12

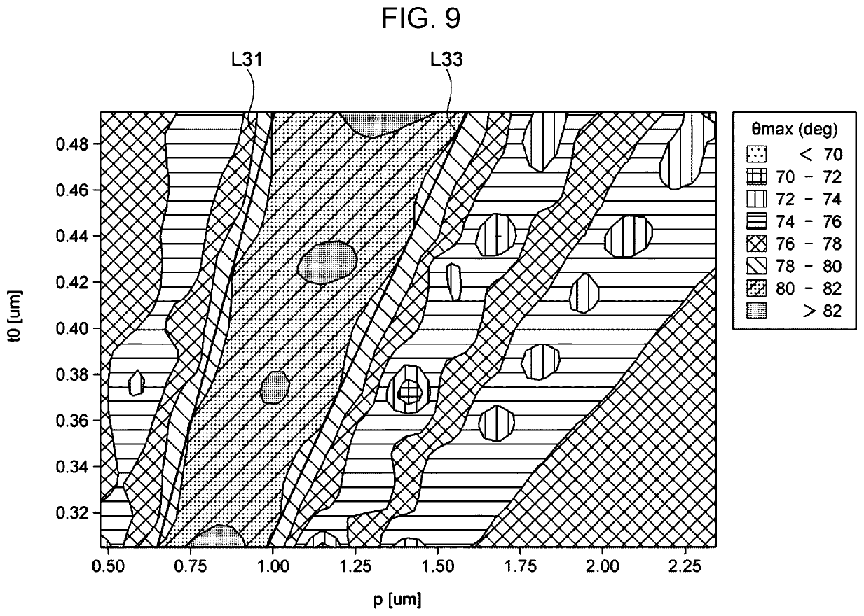

FIG. 9 is a contour chart showing a result of calculation of the maximum value θmax of the impedance phase in the third configuration example. FIG. 9 corresponds to FIG. 5. In this chart, a line L31 and a line L32 are straight lines indicating a range where the maximum value θmax is about 80° or more (or at least 78°).

In FIG. 9, as in FIG. 5, the plurality of contour lines extend substantially from the lower left to the right side of the drawing. This confirmed that the thickness t0 of the piezoelectric film 7 with which a desired maximum value θmax is achieved could be defined by its ratio to the pitch p.

In FIG. 9, when attention is focused on one value of the thickness t0 as in FIG. 5, the value of the pitch p at which the maximum value θmax is a predetermined value or more (e.g., about 80° or more, or at least 78°) is found to have a certain range. For example, the space between the line L31 and the line L32 (distance parallel to the horizontal axis) is 0.3 μm or more. Also, in the illustrated example, a region where the pitch p is about 1 μm is sandwiched between the line L31 and the line L32. It was thus confirmed that since 0.3 μm is 15% or more of 1 μm, the difference between the pitches p1 and p2 in the first excitation electrode 19A and the second excitation electrode 19B on the same piezoelectric film 7 could be set to 15% or more of the pitch p1.

In FIG. 9, as in FIG. 5, a line (not shown) parallel to the vertical axis at p=1 μm intersects the lines L32 and L31 at thicknesses t0 of 0.31 μm and 0.48 μm, respectively. From these values, the following relation (15) and relation (16) can be obtained, as in the first configuration example. When these relations are satisfied, both the first excitation electrode 19A and the second excitation electrode 19B can provide a desired maximum value θmax (about 80° or more, or at least 78°):

t0≤0.48×p1 (15),

t0≥0.31×p2 (16).

In connection with relation (15) and relation (16), the upper limit of the pitch p2 relative to the pitch p1 is defined, as in the first configuration example. That is, to satisfy both of the relations, the following relation using 0.48/0.31 (=about 1.5) needs to be satisfied:

p2≤1.5×p1 (17).

Dividing the value of the pitch p on the line L32 corresponding to one value of the thickness t0 by the value of the pitch p on the line L31 corresponding to the one value in FIG. 9 yields approximately 1.5, which substantially matches the coefficient in relation (17). This also indicates that relation (15) and relation (16) are valid.

### (Thicknesses of Multilayer Film)

In the third configuration example, as in the first configuration example, the ratios of the thickness t1 of the first layer 11 and the thickness t2 of the second layer 13 to the thickness t0 of the piezoelectric film 7 in the simulation described above were selected in such a way as to make the maximum value θmax of the impedance phase greater. The details will now be described.

With the value of the thickness t0 kept constant, the values of the thickness t1 and the thickness t2 were variously set to perform simulated calculations and determine the characteristics of the resonator 15 by the simulated calculations. The simulation conditions used here are substantially the same as the simulation conditions for FIG. 9. Simulation conditions different from those for FIG. 9 are shown below:

thickness t0 of piezoelectric film: 0.38 μm,

thickness t1 of first layer: 0.16 μm to 0.24 μm,

thickness t2 of second layer: 0.05 μm to 0.22 μm.

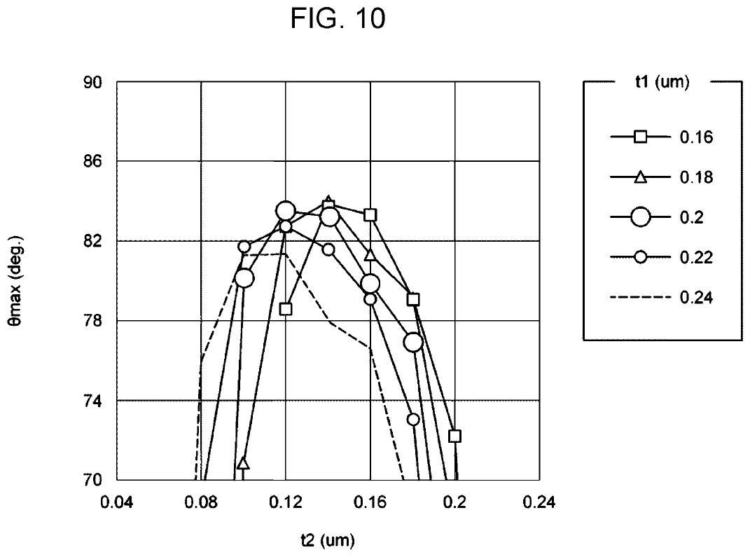

FIG. 10 is a diagram showing the maximum value θmax of the impedance phase calculated in the simulations described above. FIG. 10 corresponds to FIG. 6.

As shown in the diagram, the maximum value θmax is large when t1=0.20 μm and t2=0.12 μm. The ratio between the thicknesses t0, t1, and t2 at this point is as follows, as also mentioned in the description of the simulation conditions for FIG. 9:

t0:t1:t2=0.38:0.20:0.12.

FIG. 10 shows that even when the value of the thickness t1 and/or thickness t2 differs by about 0.02 μm from a value corresponding to the ratio, a large maximum value θmax can be obtained. Since 0.02 μm is greater than 5% of the thickness t0 (0.38 μm), the thickness t1 and the thickness t2 may each be set to fall within ±5% of the ratio described above, as in the first configuration example. That is, the thickness t1 and the thickness t2 may each be in the range defined by a corresponding one of the following relations:

0.50×t0≤t1≤0.55×t0 (18),

0.30×t0≤t2≤0.33×t0 (19).

The coefficients in relation (18) and relation (19) are determined by the following equations:

0.50=0.20/0.38×0.95,

0.55=0.20/0.38×1.05,

0.30=0.12/0.38×0.95,

0.33=0.12/0.38×1.05.

### (Summary of First to Third Configuration Examples)

The description of the first to third configuration examples shows that the effect of the relation between the pitch p of the electrode fingers 27 and the thickness t0 of the piezoelectric film 7 on the characteristics of the acoustic wave device 1 is similar among the first to third configuration examples. The range of each of t0/p1 and t0/p2 that can provide a certain magnitude of the maximum value θmax of the impedance phase is also relatively close among them.

Accordingly, for example, the following combination of relations is produced. The relations described below define ranges that include all the ranges of t0 shown in the first to third configuration examples (i.e., ranges defined by relations (4), (5), (10), (11), (15), and (16)). The thickness t0 may be set to fall within the following ranges:

t0≤0.48×p1 (20),

t0≥0.27×p2 (21).

Note that relation (20) is based on relation (15) and relation (21) is based on relation (11).

The following combination of relations is also produced. The relations described below define ranges that are included in all the ranges of t0 shown in the first to third configuration examples. The thickness t0 may be set to fall within the following ranges:

t0≤0.40×p1 (22),

t0≥0.31×p2 (23).

Note that relation (22) is based on relation (4) and relation (23) is based on relation (16).

In the foregoing description, the effect of the thickness t0 on the acoustic wave device 1 has been non-dimensionally expressed with the pitch p. Alternatively, using absolute values may be taken into account. For example, since the simulations in FIG. 5, FIG. 7, and FIG. 9 were performed on condition that the pitch p was approximately in the 0.50 μm to 2.25 μm range, the condition may be that the pitch p1 and the pitch p2 are in this range. In the drawings described above, the pitch p in the ranges indicated by the lines L11, L12, L21, L22, L31, and L32 is approximately in the 0.75 μm to 1.40 μm range. Accordingly, the condition may be that the pitch p1 and the pitch p2 are in this range. That is, the following relations,

p1≥0.75 μm, and

p2≤1.40 μm

may be satisfied.

### Example

A ladder filter was prototyped to examine its characteristics. In the ladder filter, the pitch p2 in the parallel resonator 15P was greater than the pitch p1 in the series resonator 15S by 15% or more. The material and the range of thickness of each of the piezoelectric film 7, the first layer 11, and the second layer 13 were the same as those in the second configuration example.

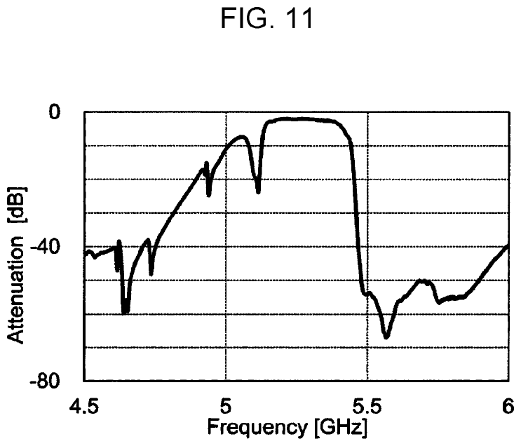

FIG. 11 is a diagram showing an example of an actually measured bandpass characteristic of a ladder filter according to Example. In this diagram, the horizontal axis represents frequency (GHz), and the vertical axis represents attenuation (dB). A line in the diagram represents changes in attenuation with respect to frequency.

This diagram shows that with the pitch p2 in the parallel resonator 15P greater than the pitch p1 in the series resonator 15S by 15% or more, the acoustic wave device 1 including the piezoelectric film 7 on the multilayer film 5 can provide filter characteristics.

### (Application of Acoustic Wave Device: Communication Apparatus)

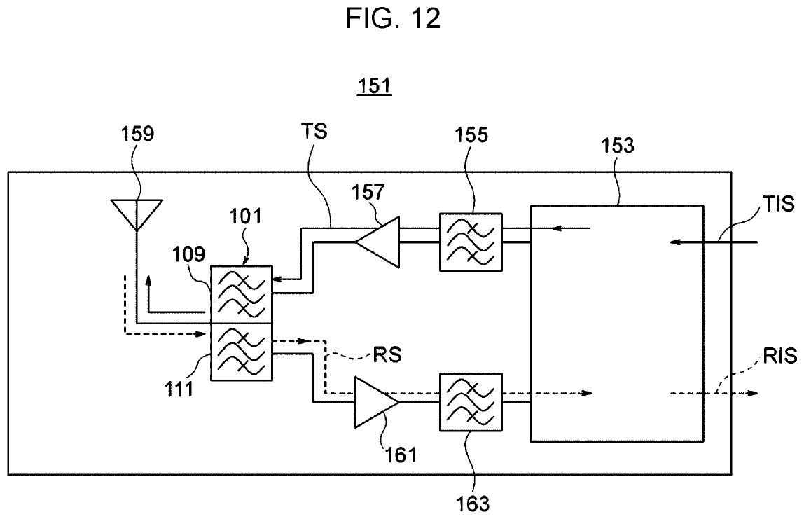

FIG. 12 is a block diagram illustrating a main part of a communication apparatus 151 which is an application of the acoustic wave device 1 (duplexer 101). The communication apparatus 151, which performs radio communication using a radio wave, includes the duplexer 101.

In the communication apparatus 151, a transmission information signal TIS, which includes information to be transmitted, is modulated and raised in frequency (i.e., converted to a high-frequency signal having a carrier frequency) into a transmission signal TS by a radio frequency integrated circuit (RF-IC) 153. After unwanted components outside the transmission pass band are eliminated by a band pass filter 155, the transmission signal TS is amplified by an amplifier 157 and received as an input signal by the duplexer 101 (transmission terminal 105). After eliminating unwanted components outside the transmission pass band from the input transmission signal TS, the duplexer 101 (transmission filter 109) outputs the resulting transmission signal TS from the antenna terminal 103 to an antenna 159. The antenna 159 converts the input electric signal (transmission signal TS) to a radio signal (radio wave) and transmits it.

Also, in the communication apparatus 151, a radio signal (radio wave) received by the antenna 159 is converted to an electric signal (reception signal RS) by the antenna 159 and received as an input signal by the duplexer 101 (antenna terminal 103). After eliminating unwanted components outside the reception pass band from the input reception signal RS, the duplexer 101 (reception filter 111) outputs the resulting reception signal RS from the reception terminal 107 to an amplifier 161. The output reception signal RS is amplified by the amplifier 161. After unwanted components outside the reception pass band are eliminated by a band pass filter 163, the reception signal RS is lowered in frequency and demodulated by the RF-IC 153 into a reception information signal RIS.

The transmission information signal TIS and the reception information signal RIS may be low-frequency signals (baseband signals) including appropriate information. For example, the transmission information signal TIS and the reception information signal RIS are analog audio signals or digital signals. The pass band of a radio signal may be appropriately set, and may be a relatively high frequency pass band (e.g., 5 GHz or higher) in the present embodiment. The modulation system may be phase modulation, amplitude modulation, frequency modulation, or a combination of two or more of them. Although the circuit system illustrated in FIG. 12 is a direct conversion system, it may be another appropriate system, such as a double superheterodyne system. FIG. 12 schematically illustrates only a main part. For example, a low-pass filter or an isolator may be added at an appropriate position, or the positions of the amplifiers may be changed.

As described above, the acoustic wave device 1 according to the present embodiment includes the substrate 3, the multilayer film 5 disposed on the substrate 3, the piezoelectric film 7 disposed on the multilayer film 5, and the first excitation electrode 19A and the second excitation electrode 19B disposed on the piezoelectric film 7. The first excitation electrode 19A has the plurality of first electrode fingers 27A arranged with the first pitch p1 in the propagation direction of an acoustic wave (D1 direction). The second excitation electrode 19B has the plurality of second electrode fingers 27B arranged with the second pitch p2 in the D1 direction. The piezoelectric film 7 is formed of a single crystal of LiTaO₃ or a single crystal of LiNbO₃. When t0 represents the thickness of the piezoelectric film 7,

1.15×p1≤p2,

t0≤0.48×p1, and

t0≥0.27×p2 are satisfied.

By setting the thickness t0 to fall within the range described above, for example, even when the difference between the pitches p1 and p2 is relatively large, both the first excitation electrode 19A and the second excitation electrode 19B can easily improve characteristics. In the acoustic wave device 1 including the piezoelectric film 7 on the multilayer film 5 and configured to deal with relatively high frequencies, the frequencies are not easily reduced by increasing the pitch p, and the excitation electrodes 19 dealing with different frequencies tend to have a large difference in pitch p. The effect of easily improving characteristics is useful for this configuration. Since the difference between the pitch p1 and the pitch p2 can be increased, for example, it is easier to provide a ladder filter that deals with relatively high frequencies (e.g., 5 GHz).

In the present embodiment, the piezoelectric film 7 may be formed of a single crystal of LiTaO₃. The multilayer film 5 may be a laminate of alternating first and second layers 11 and 13 of SiO₂ and Ta₂O₅, respectively, and

t0≤0.40×p1, and

t0≥0.29×p2, may be satisfied.

In this case, for example, as described with reference to FIG. 5, the maximum value θmax of the impedance phase can easily reach about 78° or more (or at least 76°). Accordingly, for example, the acoustic wave device 1 can exhibit good characteristics in terms of reduced loss. In particular, when

0.49×t0≤t1≤0.54×t0, and

0.38×t0≤t2≤0.42×t0, are satisfied,

where t1 and t2 represent thicknesses of the first and second layers 11 and 13, respectively, it is highly probable that the maximum value θmax will be about 78° or more (or at least 76°).

In the present embodiment, the piezoelectric film 7 may be formed of a single crystal of LiTaO₃. The multilayer film 5 may be a laminate of alternating first and second layers 11 and 13 of SiO₂ and HfO₂, respectively, and

t0≤0.41×p1, and

t0≥0.27×p2, may be satisfied.

In this case, for example, as described with reference to FIG. 7, the maximum value θmax of the impedance phase can easily reach about 82° or more. Accordingly, for example, the acoustic wave device 1 can exhibit good characteristics in terms of reduced loss. In particular, when

0.48×t0≤t1≤0.53×t0, and

0.38×t0≤t2≤0.42×t0, are satisfied,

where t1 and t2 represent thicknesses of the first and second layers 11 and 13, respectively, it is highly probable that the maximum value θmax will be about 82° or more.

In the present embodiment, the piezoelectric film 7 may be formed of a single crystal of LiNbO₃. The multilayer film 5 may be a laminate of alternating first and second layers 11 and 13 of SiO₂ and Ta₂O₅, respectively, and

t0≤0.48×p1, and

t0≥0.31×p2, may be satisfied.

In this case, for example, as described with reference to FIG. 9, the maximum value θmax of the impedance phase can easily reach about 80° or more (or at least 78°). Accordingly, for example, the acoustic wave device 1 can exhibit good characteristics in terms of reduced loss. In particular, when

0.50×t0≤t1≤0.55×t0, and

0.30×t0≤t2≤0.33×t0, are satisfied,

where t1 and t2 represent thicknesses of the first and second layers 11 and 13, respectively, it is highly probable that the maximum value θmax will be about 80° or more (or at least 78°).

The present invention is not limited to the embodiments described above and may be implemented in various ways.

For example, the configuration (e.g., composition of materials) of the multilayer film is not limited to that illustrated in the embodiments. As described above, the effect of the thickness t0 of the piezoelectric film 7 and the pitch p on the characteristics is similar among the first to third configuration examples. This also means that there is a high degree of freedom in selecting the materials of the multilayer film. Therefore, for example, the multilayer film may be formed of any appropriate materials that can confine the energy of the acoustic wave in the piezoelectric film. For example, the materials described in Prior Application 1 may be used.

The multiplexer including a plurality of filters is not limited to the duplexer. For example, the multiplexer may be a triplexer including three films, or may be a quadplexer including four filters. In some technical fields, the term “multiplexer” may be used in a narrow sense. For example, the term “multiplexer” may be used to refer only to a device that combines two or more signals and outputs the resulting signal. In the present disclosure, the term “multiplexer” is used in a broader sense. For example, the multiplexer does not necessarily need to have the function of combining signals.

### REFERENCE SIGNS LIST

1: acoustic wave device, 3: substrate, 5: multilayer film, 7: piezoelectric film, 19A: first excitation electrode, 19B: second excitation electrode

1. An acoustic wave device comprising:
a substrate;
a multilayer film disposed on the substrate;
a piezoelectric film disposed on the multilayer film; and
a first excitation electrode and a second excitation electrode disposed on the piezoelectric film,
wherein the first excitation electrode has a plurality of first electrode fingers arranged with a first pitch in a propagation direction of an acoustic wave,
the second excitation electrode has a plurality of second electrode fingers arranged with a second pitch in the propagation direction,
the piezoelectric film is formed of a single crystal of LiTaO₃ or a single crystal of LiNbO₃, and
1.15×p1≤p2,
t0≤0.48×p1, and
t0≥0.27×p2, are satisfied,
where p1 represents the first pitch, p2 represents the second pitch, and t0 represents a thickness of the piezoelectric film.

2. The acoustic wave device according to claim 1, wherein the piezoelectric film is formed of a single crystal of LiTaO₃,
the multilayer film is a laminate of alternating first and second layers of SiO₂ and Ta₂O₅, respectively, and
t0≤0.40×p1, and
t0≥0.29×p2, are satisfied.

3. The acoustic wave device according to claim 2, wherein
0.49×t0≤t1≤0.54×t0, and
0.38×t0≤t2≤0.42×t0, are satisfied,
where t1 and t2 represent thicknesses of the first and second layers, respectively.

4. The acoustic wave device according to claim 1, wherein the piezoelectric film is formed of a single crystal of LiTaO₃,
the multilayer film is a laminate of alternating first and second layers of SiO₂ and HfO₂, respectively, and
t0≤0.41×p1, and
t0≥0.27×p2, are satisfied.

5. The acoustic wave device according to claim 4, wherein
0.48×t0≤t1≤0.53×t0, and
0.38×t0≤t2≤0.42×t0, are satisfied,
where t1 and t2 represent thicknesses of the first and second layers, respectively.

6. The acoustic wave device according to claim 1, wherein
the piezoelectric film is formed of a single crystal of LiNbO₃,
the multilayer film is a laminate of alternating first and second layers of SiO₂ and Ta₂O₅, respectively, and
t0≤0.48×p1, and
t0≥0.31×p2, are satisfied.

7. The acoustic wave device according to claim 6, wherein
0.50×t0≤t1≤0.55×t0, and
0.30×t0≤t2≤0.33×t0, are satisfied,
where t1 and t2 represent thicknesses of the first and second layers, respectively.

8. The acoustic wave device according to claim 1, wherein
p1≥0.75 μm, and
p2≤1.40 μm, are satisfied.

9. The acoustic wave device according to claim 1, further comprising:
a first resonator including the first excitation electrode; and
a second resonator including the second excitation electrode, wherein
a maximum impedance phase of the first resonator is greater than or equal to 76°, and
a maximum impedance phase of the second resonator is greater than or equal to 76°.

10. The acoustic wave device according to claim 1, further comprising:
one or more series resonators each including the first excitation electrode; and
one or more parallel resonators each including the second excitation electrode,
wherein the one or more series resonators and the one or more parallel resonators are connected in a ladder configuration to form a filter.

11. A communication apparatus comprising:
the acoustic wave device according to claim 10;
an antenna electrically connected to the filter of the acoustic wave device; and
an integrated circuit element electrically connected to the antenna, with the filter interposed therebetween.
